(19) United States
(12) Patent Application Publication
(10) Pub. No.: US 2022/0050321 A1
(43) Pub. Date: Feb. 17, 2022

(54) SUBSTRATE FOR DISPLAY

(71) Applicant: LG INNOTEK CO., LTD., Seoul (KR)

(72) Inventors: Duck Hoon PARK, Seoul (KR); Hae Sik KIM, Seoul (KR); Jee Heum PAIK, Seoul (KR)

(21) Appl. No.: 17/274,871

(22) PCT Filed: Sep. 17, 2019
(86) PCT No.: PCT/KR2019/011959

§ 371 Date: Mar. 10, 2021

(30) Foreign Application Priority Data
Sep. 21, 2018 (KR) 10-2018-0114002

(51) Int. Cl. G02F 1/1333; H05K 1/02; G09F 9/30; H01L 51/00; H05K 1/11; H01L 23/538

(52) U.S. Cl. CPC G02F 1/133305; H05K 1/028; G09F 9/301; H01L 23/5384; G02F 1/133308; H05K 1/118; H01L 23/5387; H01L 51/0097

(57) ABSTRACT

A substrate for a display, according to an embodiment, comprises: a substrate having one surface and an other surface, and including a folding area and an unfolding area; and a through hole penetrating through the one surface and the other surface of the substrate, wherein the through hole includes a first through hole formed in the folding area, wherein the first through hole includes a 1-1 opening region formed by opening the one surface; and a 1-2 opening region formed by opening the other surface, wherein the 1-1 opening region and the 1-2 opening region are different from each other in size.

### TECHNICAL FIELD

The present invention relates to a substrate for a display.

### BACKGROUND ART

Recently, there is an increasing requirement for a flexible display device capable of easily carrying various applications and displaying an image on a larger screen when being carried.

Such a flexible display is folded or partially bent when being carried or stored, and may be implemented with the display unfolded when displaying images. Accordingly, an image display region may be increased, and a user may easily carry the display.

After the flexible display device is folded or bent, a restoration process of unfolding the flexible display device again may be repeated.

Accordingly, a base substrate of the display device requires strength and elasticity, and cracks and deformations should not occur in the base substrate during folding and restoring.

In addition, a difference in stress generated on one surface and the other surface of the base substrate may occur depending on a folding or bending direction.

For example, the stress on the surface of the base substrate at an inner side of the folding direction may occur to be greater than the stress on the surface of the base substrate at an outer side thereof, and the difference in the stress may cause deformation such as damage or bending of the base substrate.

Therefore, a substrate for display having a new structure is required, which may improve reliability of the display substrate applied to such a flexible display device.

### DISCLOSURE

### Technical Problem

The present invention is directed to providing a substrate for display that may improve strength thereof through a stress dispersion by folding when folding or bending a base substrate.

### Technical Solution

A substrate for display according to an embodiment includes a base substrate including one surface and the other surface, and a folding area and an unfolding area; and a through-hole passing through the one surface and the other surface of the base substrate, wherein the through-hole includes a first through-hole formed in the folding area, the first through-hole includes a 1-1 opening region formed by opening the one surface, and a 1-2 opening region formed by opening the other surface, and the 1-1 opening region and the 1-2 opening region have different sizes.

### Advantageous Effects

A substrate for display according to an embodiment can mitigate an influence of the base substrate due to a difference in stress according to a direction in which the base substrate is folded or bent as well as an influence of the base substrate due to stress generated when the base substrate is folded or bent.

That is, in the display substrate according to an embodiment, it is possible to prevent the base substrate from being deformed or damaged in a folding area due to the stress generated when the base substrate is folded or bent by forming a plurality of through-holes passing through the base substrate in the folding area of the base substrate.

In addition, in the display substrate according to an embodiment, it is possible to prevent the base substrate from being deformed or damaged in the folding area due to a difference in the stress according to a direction in which the base substrate is folded or bent by differently forming a size of the through-hole formed in the base substrate inside and outside the folding direction.

That is, stress dispersion from the inner side in the folding direction in which stress is concentrated may be further increased by forming the size of the through-hole to be larger at the inner side in the folding direction than at the outer side. Therefore, a bending phenomenon of the base substrate due to the stress difference in one surface or the other surface of the base substrate according to the folding direction may be prevented, and the damage of the base substrate may be prevented by alleviating stress concentration in the folding direction.

### DESCRIPTION OF DRAWINGS

FIG. 1 is a perspective view of a substrate for display according to an embodiment.

FIG. 2 is a view illustrating a top view of one surface of a substrate for display according to an embodiment.

FIG. 3 is a view illustrating a top view of the other surface of a substrate for display according to an embodiment.

FIG. 4 is a view illustrating a cross-sectional view taken along region A-A′ in FIG. 2.

FIG. 5 is a view illustrating another top view of one surface of a substrate for display according to an embodiment.

FIG. 6 is a view illustrating another top view of the other surface of a substrate for display according to an embodiment.

FIG. 7 is a view illustrating a cross-sectional view taken along region B-B′ in FIG. 5.

FIG. 8 is a view illustrating still another top view of one surface of a substrate for display according to an embodiment.

FIG. 9 is a view illustrating still another top view of the other surface of a substrate for display according to an embodiment.

FIG. 10 is a view illustrating a cross-sectional view taken along region C-C′ in FIG. 8.

FIG. 11 is a view for describing an example in which a substrate for display according to an embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless In detail stated in the phrase, and may include at least one of all combinations that may be combined in A, B, and C when described in “at least one (or more) of A (and), B, and C”.

Further, in describing the elements of the embodiments of the present invention, the terms such as first, second, A, B, (A, and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, a substrate for display according to an embodiment will be described with reference to drawings.

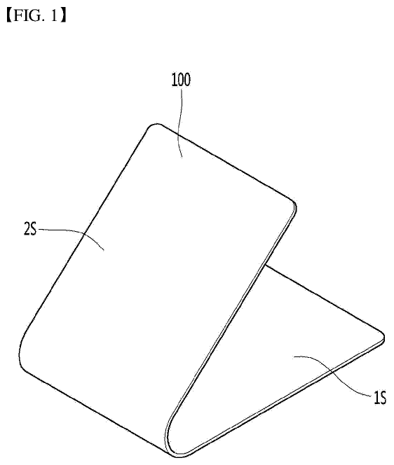

Referring to FIGS. 1 to 4, a substrate for display according to an embodiment includes a base substrate 100.

The base substrate 100 may include metals, metal alloys, plastics, composite materials (e.g., carbon fiber reinforced plastics, magnetic or conductive materials, glass fiber reinforced materials, etc.), ceramics, sapphire, glass, and the like.

As described above, in case of the base substrate 100 having rigidity, when bending it in one direction, a problem that the base substrate is damaged while being folded or bent due to a tensile stress or a compressive stress generated by bending may occur.

The substrate for display according to an embodiment may prevent the base substrate from being damaged by such folding or bending.

Referring to FIG. 1, the base substrate 100 may be bent in one direction.

In detail, the base substrate 100 may include one surface 1S and the other surface 2S opposite to the one surface 1S. In the base substrate 100, the one surface IS or the other surface 2S may be bent to face each other.

In a following description, as shown in FIG. 1, the base substrate 100 will be described with respect to bending in a direction in which the one surfaces 1S face each other.

In the base substrate 100, a first area 1A and a second area 2A may be defined. The first area 1A and the second area 2A may be areas defined when the base substrate 100 is bent in the direction in which the one surfaces 1S face each other.

In detail, the base substrate 100 is bent in one direction, and the base substrate 100 may be divided into the first area 1A which is a folded area (folding area) and the second area 2A which is an unfolded area (unfolding area). The second area may be defined as an area or the like that is flat or is folded with a smaller curvature than the first area.

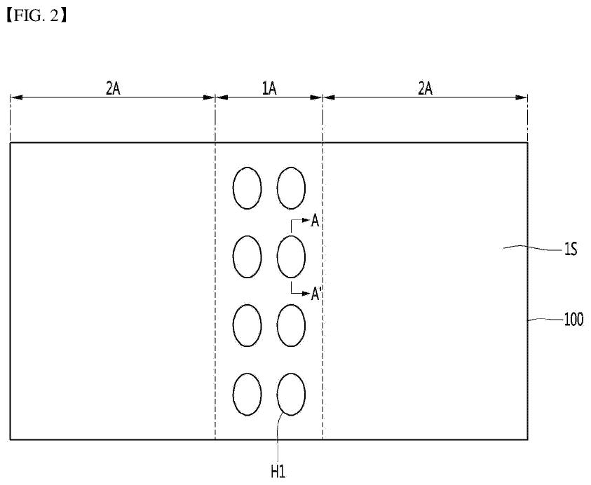

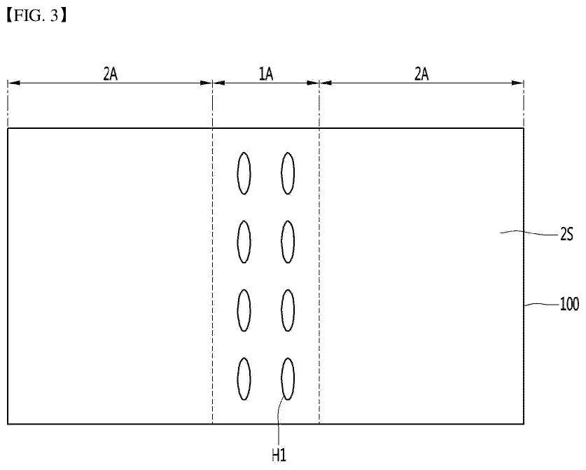

In detail, referring to FIG. 2 and FIG. 3, the base substrate 100 may include a first area 1A that is an area in which the base substrate 100 is bent. The base substrate 100 may include a second area 2A that is not bent and is disposed adjacent to the first area 1A.

For example, the second area 2A may be formed on the left side and the right side of the first area 1A with respect to the direction in which the base substrate 100 is bent.

The first area 1A and the second area 2A may be formed on the same base substrate 100. That is, the first area 1A and the second area 2A are not separated on the same base substrate 100, and may be formed integrally with each other.

A size of the first area 1A and that of the second area 2A may be different from each other. In detail, the size of the second area 2A may be larger than that of the first area 1A.

FIGS. 2 and 3 illustrate that the first area 1A is positioned in a central portion of the base substrate 100, but the embodiment is not limited thereto. That is, the first area 1A may be positioned in one end and an end area of the base substrate 100. That is, the first area 1A may be positioned at one end and the end area of the base substrate 100 such that the size of the second area 2A is asymmetric.

Holes may be formed in the first area 1A. In detail, the first area 1A may be formed with a plurality of first through-holes H1 that are spaced apart from each other. The first through-hole H1 may be formed passing through the base substrate 100. In detail, the first through-hole H1 may be formed passing through one surface 1S and the other surface 2S of the base substrate 100.

That is, the first through-hole H1 may be formed passing through the one surface 1S positioned inside a folding direction and the other surface 2S disposed outside the folding direction.

The first through-holes H1 may be formed in a regular pattern in the first area 1A. Alternatively, the first through-holes H1 may be formed in a random pattern in the first area 1A.

The first through-hole H1 may be formed while having a curved surface. In detail, the first through-hole H1 may be formed in a shape having a curved surface such as an elliptical shape, a hemispherical shape, a circular shape, or the like.

However, the embodiment is not limited thereto, and the first through-hole H1 may be formed in a polygonal shape such as a triangle, a square, or the like.

Referring to FIGS. 2 to 4, the first through-hole H1 may be formed in different sizes on one surface and the other surface of the base substrate 100.

In detail, the first through-hole H1 includes a 1-1 opening region OA1-1 in which the one surface 1S of the base substrate 100 is opened and a 1-2 opening region OA1-2 in which the other surface 2S of the base substrate 100 is opened.

The 1-1 opening region OA1-1 and the 1-2 opening region OA1-2 may be overlapped in each first through-hole to form one hole.

The 1-1 opening region OA1-1 may include a curved surface. That is, an inner surface of the 1-1 opening region OA1-1 may include a curved surface.

The 1-1 opening region OA1-1 may extend in a depth direction of the base substrate 100 and a width thereof may be reduced. That is, it may extend in a direction of the other surface 2S from the one surface 1S of the base substrate 100 and the width thereof may be reduced.

The 1-2 opening region OA1-2 may include a curved surface. That is, an inner surface of the 1-2 opening region OA1-2 may include a curved surface.

The 1-2 opening region OA1-2 may extend in the depth direction of the base substrate 100 and a width thereof may be reduced. That is, it may extend in a direction of the one surface 1S from the other surface 2S of the base substrate 100 and the width thereof may be reduced.

The 1-1 opening region OA1-1 and the 1-2 opening region OA1-2 may be formed in different sizes. For example, the 1-1 opening region OA1-1 may have a 1-1 width W1-1 in a direction parallel to a folding direction in which the base substrate 100 is bent. In addition, the0 1-2 opening region OA1-2 may have a 1-2 width W1-2 in a direction parallel to a folding direction in which the base substrate 100 is bent.

Here, the 1-1 width W1-1 and the 1-2 width W1-2 may be defined as a maximum width of the 1-1 opening region OA1-1 and the 1-2 opening region OA1-2, respectively. In detail, the 1-1 width W1-1 and the 1-2 width W1-2 may be defined as a maximum particle size of the 1-1 opening region OA1-1 and the 1-2 opening region OA1-2, respectively.

In the first through-hole H1, the 1-1 width W1-1 and the 1-2 width W1-2 may be formed in different sizes. In detail, in the first through-hole H1, the 1-1 width W1-1 may be formed larger than the 1-2 width W1-2.

That is, the 1-1 width W1-1 of the 1-1 opening region OA1-1 formed inside the folding direction in which the base substrate 100 is bent, that is, on the one surface 1S of the base substrate 100 may be formed larger than the 1-2 width W1-2 of the 1-2 opening region OA1-2 formed outside the folding direction in which the base substrate 100 is bent, that is, on the other surface 2S of the base substrate 100.

The first through-holes H1 formed in the first area 1A may serve a role of dispersing stress generated in the first area 1A when the base substrate 100 is bent.

In detail, the first through-holes H1 may effectively disperse compressive stress or tensile stress generated when the base substrate 100 is bent. Accordingly, it is possible to prevent the base substrate from being deformed by occurrence of cracks, damage, bending, or the like in the base substrate due to stress generated by deformation of the base substrate 100 being concentrated in a specific area.

Meanwhile, the compressive stress or tensile stress may be generated by different forces between the one surface and the other surface of the base substrate 100.

In detail, when the base substrate 100 is bent so that the one surface of the base substrate 100 is disposed inside the folding direction as shown in FIG. 1, the stress generated on the one surface of the base substrate 100 may occur to be larger than the stress generated on the other surface of the base substrate 100.

Accordingly, in the first area 1A, cracks or the like may occur only on the one surface of the base substrate 100 along the direction in which the base substrate 100 is bent. In addition, the base substrate may be bent due to a difference in stress between the first area 1A and the second area 2A.

Accordingly, in a substrate for display according to an embodiment, a hole may be formed in an area in which the base substrate is folded, and at this time, a width of an opening region formed on a surface in the direction in which the base substrate is bent may be formed larger than that of an opening region of an opposite area thereof, thereby compensating for a difference in stress according to a bending direction.

In detail, the 1-1 width W1-1 of the 1-1 opening region OA1-1 and the 1-2 width W1-2 of the 1-2 opening region OA1-2 may satisfy the following Equation 1.

1.0t≤1-1 width

0.8t≤1-2 width≤1.1t [Equation 1]

(where t is a thickness of a base substrate)

Meanwhile, the thickness t of the base substrate 100 may be about 0.01 mm to 2 mm. When the thickness of the base substrate 100 is less than about 0.1 mm, it is easy to fold or bend the base substrate 100, but rigidity of the base substrate 100 is reduced, and thus it may be easily damaged by an external impact. When the thickness of the base substrate 100 exceeds about 2 mm, stress is greatly generated due to the thickness of the base substrate 100 when the base substrate 100 is folded or bent, and thus the base substrate may be damaged, or a bending size, that is, a curvature of the base substrate may be limited.

In addition, when a size of the 1-1 width W1-1 is less than about 1 times the thickness t of the base substrate 100, the stress generated when the base substrate is folded or bent in a direction in which the one surfaces face each other may not be effectively dispersed by the 1-1 opening region, and thus damage or bending of the base substrate due to stress may occur.

Further, when a size of the 1-2 width W1-2 is less than about 0.8 times the thickness t of the base substrate 100, the stress generated when the base substrate 100 is folded or bent may not be effectively dispersed, and when the size of the 1-2 width W1-2 exceeds about 1.1 times, strength of the base substrate 100 may be lowered.

Furthermore, a difference W1-1-W1-2 between the 1-1 width W1-1 of the 1-1 opening region OA1-1 and the 1-2 width W1-2 of the 1-2 opening region OA1-2 may satisfy the following Equation 2.

0.2t≤1-1 width-1-2 width [Equation 2]

(where t is a thickness of a base substrate)

In detail, when the difference W1-1-W1-2 between the 1-1 width W1-1 of the 1-1 opening region OA1-1 and the 1-2 width W1-2 of the 1-2 opening region OA1-2 is less than 0.2 times the thickness t of the base substrate, since the size of the 1-1 opening region may not be increased sufficiently, or the size of the 1-2 width W1-2 should be increased, the stress generated when the base substrate is folded or bent in a direction in which the one surfaces face each other may not be effectively dispersed by the 1-1 opening region, and thus damage of the base substrate due to stress may occur, and strength of the base substrate may be lowered.

Meanwhile, in the first through-hole H1, a first contact region CA1 in which the 1-1 opening region OA1-1 and the 1-2 opening region OA1-2 are in contact with each other may be defined. That is, as shown in FIG. 4, in the through-hole H1, the first contact region CA1 in which the 1-1 opening region OA1-1 and the 1-2 opening region OA1-2 communicate with each other may be formed.

At this time, a width of the first contact region CA1 may satisfy the following Equation 3.

1-1 width-0.5t≤width of first contact region≤1-1 width-0.3t [Equation 3]

(where t is a thickness of a base substrate)

When a width of the first contact region CA1 is less than 0.5 times a difference between the 1-1 width and the thickness of the base substrate, an area in which the 1-1 opening region OA1-1 and the 1-2 opening region OA1-2 communicate with each other is narrowed, and thus etching factors of the 1-1 opening region OA1-1 and the 1-2 opening region OA1-2 may be reduced.

When the width of the first contact region CA1 exceeds a difference of 0.3 times the 1-1 width and the thickness of the base substrate, the area in which the 1-1 opening region OA1-1 and the 1-2 opening region OA1-2 communicate with each other is widened, and thus the etching factors of the 1-1 opening region OA1-1 and the 1-2 opening region OA1-2 may be increased.

That is, when the etching factor is about 2 to 3, the first through-hole H1 according to an embodiment may have maximum efficiency in stress dispersion, and may control the width of the first contact region to satisfy the etching factor.

In addition, a depth of the 1-1 opening region OA1-1 may satisfy the following Equation 4.

0.5t≤depth of 1-1 opening region [Equation 4]

(where t is a thickness of a base substrate)

That is, the depth of the 1-1 opening region OA1-1 may be 0.5 times or more with respect to the thickness t of the base substrate 100. That is, a depth d1-1 of the 1-1 opening region OA1-1 may be formed to be half the total thickness of the base substrate 100 or more. That is, the depth d1-1 of the 1-1 opening region OA1-1 may be formed to be equal to or deeper than a depth d1-2 of the 1-2 opening region OA1-2.

That is, the 1-1 opening region OA1-1 may be formed the depth of the 1-2 opening region OA1-2 or more in order to increase a stress dispersion effect due to folding. That is, when the depth of the 1-1 opening region OA1-1 is less than 0.5 times the thickness t of the base substrate 100, the depth of the 1-2 opening region OA1-2 is rather increased, and thus stress dispersion in the 1-1 opening region OA1-1 may not be effectively implemented.

In a substrate for display according to an embodiment, it is possible to mitigate an influence of the base substrate due to a difference in stress according to a direction in which the base substrate is folded or bent as well as an influence of the base substrate due to stress generated when the base substrate is folded or bent.

That is, in the substrate for display according to an embodiment, it is possible to prevent the base substrate from being deformed or damaged in a folding area due to the stress generated when the base substrate is folded or bent by forming a plurality of through-holes passing through the base substrate in the folding area of the base substrate.

In addition, in the substrate for display according to an embodiment, it is possible to prevent the base substrate from being deformed or damaged in the folding area due to a difference in the stress according to a direction in which the base substrate is folded or bent by differently forming a size of the through-hole formed in the base substrate inside and outside the folding direction.

That is, stress dispersion from the inner side in the folding direction in which stress is concentrated may be further increased by forming the size of the through-hole to be larger at the inner side in the folding direction than at the outer side. Therefore, a bending phenomenon of the base substrate due to the stress difference in one surface or the other surface of the base substrate according to the folding direction may be prevented, and the damage of the base substrate may be prevented by alleviating stress concentration in the folding direction.

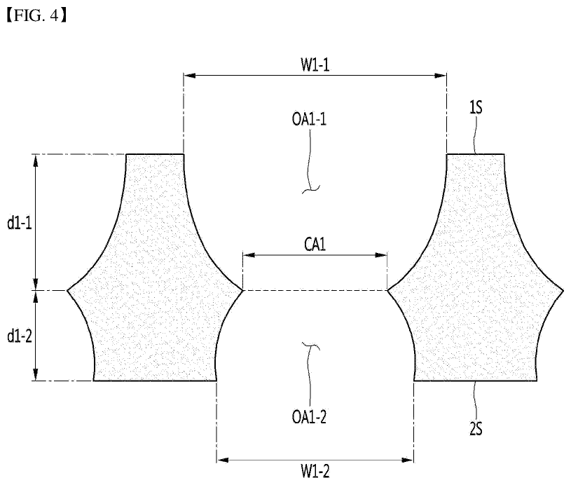

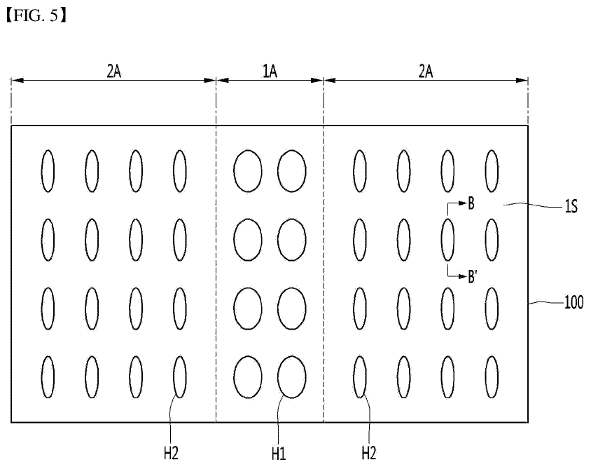

Hereinafter, a substrate for display according to another embodiment will be described with reference to FIGS. 5 to 7.

Referring to FIGS. 5 to 7, in the substrate for display according to another embodiment, holes may be formed in a second area of a base substrate 100.

In detail, the base substrate 100 may include a first area 1A and a second area 2A, a first through-hole H1 may be formed in the first area 1A, and a second through-hole H2 may be formed in the second area 2A.

Since the first through-holes H1 formed in the first area 1A is the same as the embodiment described above, a following description is omitted. That is, the first through-hole of the above-described embodiment may be combined with the following other embodiments.

A plurality of second through-holes H2 spaced apart from each other may be formed in the second area 2A.

The second through-holes H2 may be formed to be overlapped with one surface and the other surface of the second area 2A of the base substrate 100 and to pass through the base substrate 100.

That is, the second through-hole H2 may include a 2-1 opening region OA2-1 in which the one surface is open and a 2-2 opening region OA2-2 in which the other surface is open.

The 2-1 opening region OA2-1 may include a curved surface. That is, an inner surface of the 2-1 opening region OA2-1 may include a curved surface.

The 2-1 opening region OA2-1 may extend in a depth direction of the base substrate 100 and a width thereof may be reduced. That is, it may extend in a direction of the other surface 2S from the one surface 1S of the base substrate 100 and the width thereof may be reduced.

The 2-2 opening region OA2-2 may include a curved surface. That is, an inner surface of the 2-2 opening region OA2-2 may include a curved surface.

The 2-2 opening region OA2-2 may extend in the depth direction of the base substrate 100 and a width thereof may be reduced. That is, it may extend in a direction of the one surface 1S from the other surface 2S of the base substrate 100 and the width thereof may be reduced.

The 2-1 opening region OA2-1 may have a 2-1 width W2-1 in a direction parallel to a folding direction in which the base substrate 100 is bent. In addition, the 2-2 opening region 0A2-2 may have a 2-2 width W2-2 in a direction parallel to a folding direction in which the base substrate 100 is bent.

Sizes of the 2-1 width W2-1 and the 2-2 width W2-2 may be the same as or similar to each other. That is, the sizes of the 2-1 width W2-1 and the 2-2 width W2-2 may be equal to each other or similar to each other by a difference due to tolerance.

In addition, a depth d2-1 of the 2-1 opening region OA2-1 and a depth d2-2 of the 2-2 opening region OA2-2 may be equal to or similar to each other. That is, the depth d2-1 of the 2-1 opening region OA2-1 and the depth d2-2 of the 2-2 opening region OA2-2 may be equal to or similar to each other by a difference due to tolerance.

That is, the second through-hole H2 may be formed in a shape in which the 2-1 opening region OA2-1 and 2-2 opening region OA2-2 formed on one surface and the other surface of the base substrate 100 may correspond to each other.

The sizes of the 2-1 width W2-1 and the 2-2 width W2-2 may be different from the size of the 1-1 width W1-1 of the first through-hole H1. In detail, the sizes of the 2-1 width W2-1 and the 2-2 width W2-2 may be smaller than that of the 1-1 width W1-1.

In addition, the sizes of the 2-1 width W2-1 and the 2-2 width W2-2 may be equal to or different from that of the 1-2 width W1-2 of the first through-hole H1.

For example, the sizes of the 2-1 width W2-1 and the 2-2 width W2-2 may be formed in a range from the size of the 1-2 width W1-2 to the size of the 1-1 width W1-1.

In addition, the shape of the 1-2 opening region OA1-2 and the shape of the 2-2 opening region OA2-2 may correspond to each other. That is, the shape of the 1-2 opening region OA1-2 and the shape of the 2-2 opening region OA2-2 may be formed in the same shape.

In this case, when the sizes of the 2-1 width W2-1 and the 2-2 width W2-2 are formed to be equal to that of the 1-2 width W1-2, the 1-2 opening region OA1-2 and the 2-2 opening region OA2-2 may be simultaneously formed in the same process. Accordingly, process efficiency of manufacturing of the substrate for display may be improved.

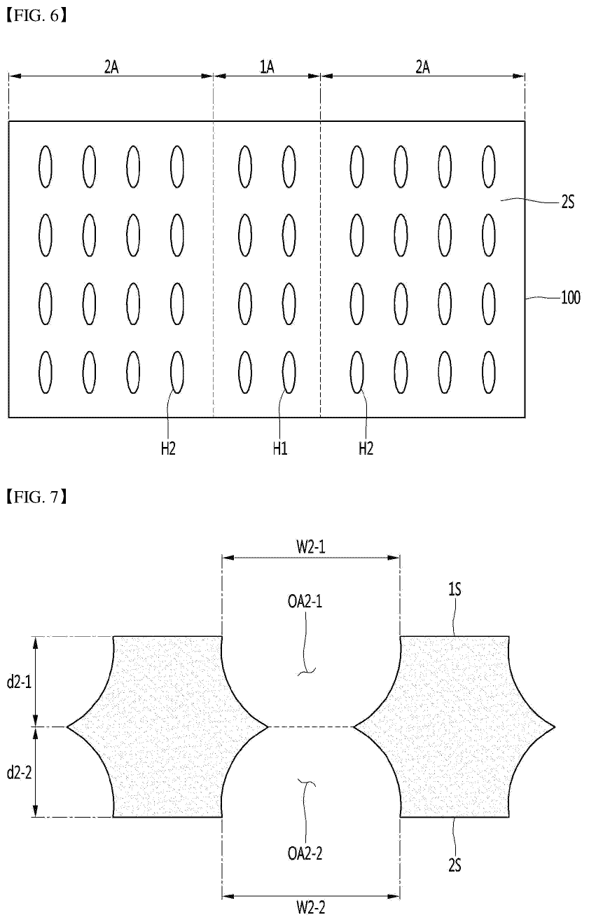

Meanwhile, in the second through-hole H2, a second contact region CA2 in which the 2-1 opening region OA2-1 and the 2-2 opening region OA2-2 are in contact with each other may be defined. That is, as shown in FIG. 7, in the through-hole H2, a second contact region CA2 in which the 2-1 opening region OA2-1 and the 2-2 opening region OA2-2 communicate with each other may be formed.

A size of the second contact region CA2 may be different from a size of the first contact region CA1 of the first through-hole H1.

In the substrate for display according to another embodiment, holes may be formed in a non-bending area in addition to a bending area.

That is, through-holes may be formed in the whole area of the base substrate. Compressive or tensile stress generated when the base substrate is bent is transmitted to an area which is not bent, so that the through-holes may prevent the substrate from being bent in the area which is not bent.

That is, it is possible to prevent the stress from concentrating on a specific area by dispersing the stress is in the second area by the through-holes.

Therefore, it is possible to prevent deformation such as a bending in the second area while preventing cracks and deformation in the first area.

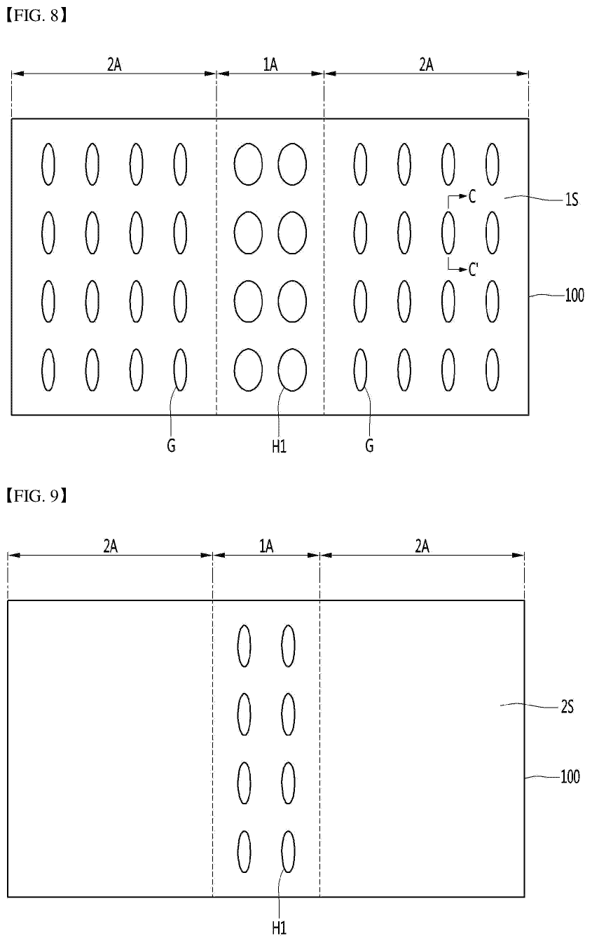

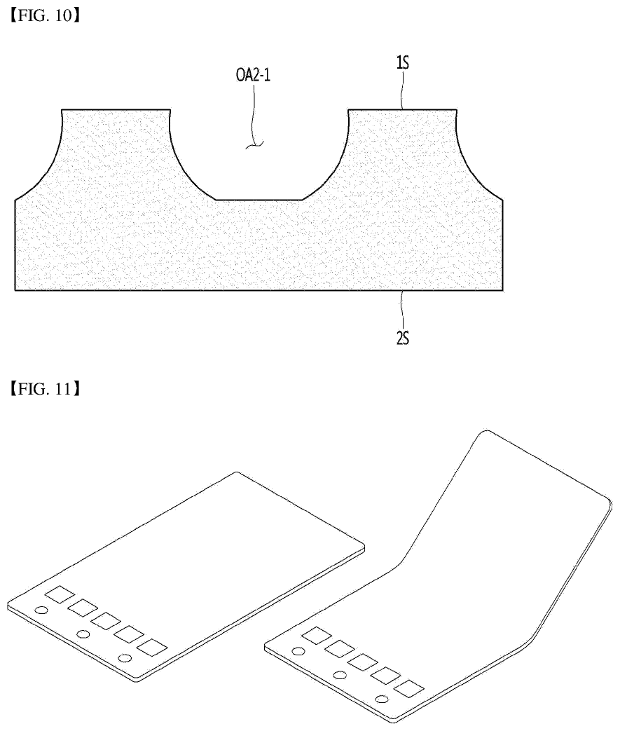

Hereinafter, a substrate for display according to still another embodiment will be described with reference to FIGS. 8 to 10.

Referring to FIGS. 8 to 10, in a substrate for display according to still another embodiment, grooves may be formed in a second area of a base substrate 100.

In detail, the base substrate 100 may include a first area 1A and a second area 2A, and a first through-hole H1 may be formed in the first area 1A, and grooves G may be formed in the second area 2A.

Since the first through-holes H1 formed in the first area 1A are the same as the embodiment described above, a following description is omitted. That is, the first through-hole of the above-described embodiment may be combined with the following other embodiments.

A plurality of grooves G spaced apart from each other may be formed in the second area 2A.

The grooves G may be formed only on one surface of both surfaces of the second area 2A of the base substrate 100.

For example, the grooves G may be formed only on an inner surface in which the base substrate is bent, that is, on one surface 15 of the base substrate 100. That is, the grooves G may be formed in a thickness direction of the base substrate on the one surface 15 of the base substrate 100, and may not be formed on the other surface of the base substrate 100. That is, the grooves G do not pass through the base substrate 100.

The groove G may include a 2-1 opening region OA2-1 of the one surface.

The 2-1 opening region OA2-1 may include a curved surface. That is, an inner surface of the 2-1 opening region OA2-1 may include a curved surface.

The 2-1 opening region OA2-1 may extend in a depth direction of the base substrate 100 and a width thereof may be reduced. That is, it may extend in a direction of the other surface 2S from the one surface 1S of the base substrate 100 and the width thereof may be reduced.

The 2-1 opening region OA2-1 may have a 2-1 width W2-1 in a direction parallel to a folding direction in which the base substrate 100 is bent.

A size of the 2-1 width W2-1 may be different from that of the 1-1 width W1-1 of the first hole H1. In detail, the size of the 2-1 width W2-1 may be smaller than that of the 1-1 width W1-1.

In addition, the size of the 2-1 width W2-1 may be equal to or different from that of the 1-2 width W1-2 of the first through-hole H1.

For example, the size of the 2-1 width W2-1 may be formed a range from the size of the 1-2 width W1-2 to the size of the 1-1 width W1-1.

In addition, the shape of the 1-2 opening region OA1-2 and the shape of the 2-1 opening region OA2-1 may correspond to each other. That is, the shape of the 1-2 opening region OA1-2 and the shape of the 2-1 opening region OA2-1 may be formed in the same shape.

In this case, when the size of the 2-1 width W2-1 is formed to be equal to that of the 1-2 width W1-2, the 1-2 opening region OA1-2 is formed and the 2-1 opening region OA2-2 may be formed simultaneously in the same process. Accordingly, process efficiency of manufacturing of the substrate for display may be improved.

In the substrate for display according to another embodiment, holes may be formed in a non-bending area in addition to a bending area.

That is, holes and grooves may be formed in the whole area of the base substrate. Compressive or tensile stress generated when the base substrate is bent is transmitted to an area which is not bent, so that grooves may prevent the substrate from being bent in the area which is not bent.

That is, it is possible to prevent the stress from concentrating on a specific area by dispersing the stress is in the second area by the grooves.

Therefore, it is possible to prevent deformation such as a bending in the second area while preventing cracks and deformation in the first area.

FIG. 11 is a view for describing an example in which a substrate for display according to an embodiment is applied.

Referring to FIG. 11, the substrate for display according to the embodiment may be applied to a display device that displays a display.

For example, the substrate for display according to the embodiment may be applied to a display device such as a mobile phone or a tablet.

Such a substrate for display may be applied to display devices such as a mobile phone, a tablet, and the like that are flexible, bent or folded.

The substrate for display is applied to the display devices such as the mobile phone, the tablet, and the like that are flexible, bent or folded, and may prevent the base substrate from being damaged due to stress in the display device that is repeatedly folded or restored.

The characteristics, structures, effects, and the like described in the above embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, the above description of the embodiments is merely examples and does not limit the present invention. It would be apparent to those of ordinary skill in the art that the present invention may be easily embodied in many different forms without changing the technical idea or essential features thereof. For example, elements of the exemplary embodiments described herein may be modified and realized. Also, it should be construed that differences related to such changes and applications are included in the scope of the present invention defined in the appended claims.

1. A substrate for display comprising:
a base substrate including one surface and the other surface, and including a first area and a second area; and
a plurality of through-holes passing through the one surface and the other surface of the base substrate,
wherein the first area is defined as a folding area, and the second area is defined as an unfolding area, and
the through-hole includes a first through-hole formed in the first area,
wherein the first through-hole includes a 1-1 opening region formed by opening the one surface, and a 1-2 opening region formed by opening the other surface,
the base substrate is bent in a direction in which the first areas on the one surface face each other, and
a size of the 1-1 opening region is larger than a size of the 1-2 opening region.

2-10. (canceled)

11. The substrate for display of claim 1, wherein a thickness of the base substrate is 0.01 mm to 2 mm.

12. The substrate for display of claim 11, wherein a 1-1 width defined as the maximum width of the 1-1 opening region and a 1-2 width defined as the maximum width of the 1-2 opening region satisfy the following Equation 1.
1.0t≤1-1 width
0.8t≤1-2 width≤1.1t [Equation 1]
(where t is a thickness of the base substrate)

13. The substrate for display of claim 11, wherein a difference between a 1-1 width defined as the maximum width of the 1-1 opening region and a 1-2 width defined as the maximum width of the 1-2 opening region satisfies the following Equation 2.
0.2t≤1-1 width-1-2 width [Equation 2]
(where t is a thickness of the base substrate)

14. The substrate for display of claim 11, wherein the maximum width of the 1-1 opening region is defined as a 1-1 width,
the maximum width of the 1-2 opening region is defined as a 1-2 width, and
a width of a first contact region where the 1-1 opening region and the 1-2 opening region are in contact satisfies the following Equation 3.
1-1 width-0.5t width of first contact region 1-1 width-0.3t [Equation 3]
(where, t is a thickness of the base substrate)

15. The substrate for display of claim 11, wherein a depth of the 1-1 opening region satisfies the following Equation 4.
0.5t≤depth of 1-1 opening region [Equation 4]
(where t is a thickness of the base substrate)

16. The substrate for display of claim 1, wherein an inner surface of the 1-1 opening region and an inner surface of the 1-2 opening region include a curved surface.

17. The substrate for display of claim 1, wherein a width of the 1-1 opening region becomes narrower extending from the one surface toward the other surface of the base substrate, and
a width of the 1-2 opening region becomes narrower extending from the other surface toward the one surface of the base substrate.

18. The substrate for display of claim 1, wherein one 1-1 opening region and one 1-2 opening region overlap each other in the first through-hole to form one hole.

19. The substrate for display of claim 1, wherein the second area of the base substrate includes a plurality of grooves formed in the one surface or the other surface.

20. The substrate for display of claim 19, wherein the groove includes a 2-1 opening region, and
an inner surface of the 2-1 opening region includes a curved surface.

21. The substrate for display of claim 20, wherein the base substrate is bent in the direction in which the first areas on the one surface face each other,
the maximum width of the 1-1 opening region is defined as a 1-1 width,
the maximum width of the 1-2 opening region is defined as a 1-2 width,
the maximum width of the 2-1 opening region is defined as a 2-1 width, and
a size of the 2-1 width is formed between a size of the 1-2 width and a size of the 1-1 width.

22. The substrate for display of claim 20, wherein the 2-1 opening region has the same shape as that of the 1-2 opening region.

23. The substrate for display of claim 1, wherein the through-hole further includes a second through-hole formed in the second area,
the second through-hole includes a 2-1 opening region formed by opening the one surface, and a 2-2 opening region formed by opening the other surface, and
shapes of the 2-1 opening region and the 2-2 opening region correspond to a shape of the 1-2 opening region.

24. The substrate for display of claim 12, wherein the through-hole further includes a second through-hole formed in the second area,
the second through-hole includes a 2-1 opening region formed by opening the one surface, and a 2-2 opening region formed by opening the other surface, and
a size of the 2-1 opening region and the 2-2 opening region is between the size of the 1-2 width and that of the 1-1 width.

25. The substrate for display of claim 14, wherein the through-hole further includes a second through-hole formed in the second area,
the second through-hole includes a 2-1 opening region formed by opening the one surface, and a 2-2 opening region formed by opening the other surface, and
a width of a second contact region where the 2-1 opening region contacts the 2-2 opening region is smaller than the width of the second contact region.
